(19) United States
(12) Patent Application Publication
(10) Pub. No.: US 2003/0082922 A1
(43) Pub. Date: May 1, 2003

(54) Method of fabricating integrated circuit having shallow junction

(76) Inventors: Seong-jae Lee, Daejon (KR); Won-ju Cho, Daejon (KR); Kyoung-wan Park, Daejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/033,394

(22) Filed: Dec. 28, 2001

(30) Foreign Application Priority Data
Oct. 29, 2001 (KR) 01-66742

(51) Int. Cl. H01L 21/00; H01L 21/31; H01L 21/469

(52) U.S. Cl. 438/766; 438/96; 438/789

(57) ABSTRACT

A method of fabricating an integrated circuit having shallow junctions is provided. A SOG layer containing impurities is formed on a semiconductor substrate. Impurity ions are additionally implanted into the SOG layer by a plasma ion implantation method to increase the concentration of impurities in the SOG layer. The impurity ions contained in the SOG layer having the increased concentration of impurities are rapidly heat-treated and diffused into the semiconductor substrate by a solid phase diffusion method to form shallow junctions. As a result, the concentration of impurities is precisely controlled by the plasma ion implantation method, and impurity ions are not directly implanted into the semiconductor substrate. Thus, the crystal structure of the semiconductor substrate is not damaged. Moreover, if the method of fabricating the integration circuit having the shallow junctions is applied after a gate electrode is formed, a LDD region and a highly doped source/drain region can be formed by a self-aligned method.

### BACKGROUND OF THE INVENTION

1. Field of the Invention

The present invention relates to a method of fabricating an integrated circuit, and more particularly, to a method of fabricating an integrated circuit having a shallow junction.

2. Description of the Related Art

In general, an integrated circuit (IC) is a set of discrete circuit devices including a transistor, a diode, a condenser, resistance and the like on a substrate, which are connected to one another to carry out a particular function in an electric circuit. The IC may be classified into a bipolar IC and a MOS IC according to kinds of transistors used. The bipolar IC uses an n-p-n transistor or a p-n-p transistor and the MOS IC uses a metal oxide silicon (MOS) transistor.

As the IC, particularly the MOS IC, becomes highly integrated, it requires a shallow junction. The shallow junction is a junction which is formed to a shallow depth into a substrate, has a high concentration and high activation rate of a dopant, and has an abrupt junction profile in horizontal and vertical directions.

The shallow junction is conventionally formed by an ion implantation method or a solid phase diffusion method. In the ion implantation method, an ion implanter highly accelerates impurity ions with a high acceleration voltage and then implants the impurity ions into a substrate to form a shallow junction. In the solid phase diffusion method, a solid phase diffusion source is formed on a substrate, and then a dopant in the solid phase diffusion source is diffused and doped into the substrate to form a shallow junction.

In order to avoid the confusion of the terminology used in this detailed description of the present invention, impurities implanted by the ion implantation method are described as “impurities”, and impurities implanted by the solid phase diffusion method are described as “dopant”. Also, implanting ionic impurities is referred to as “ion implantation”, and diffusing impurities of a substrate already containing impurities by the solid phase diffusion method is referred to as “doping”.

The ion implantation method damages the crystal structure of the substrate because of the kinetic energy of impurity ions, and thus dislocations occur. The dislocations cause a sharp diffusion of the implanted impurities as well as a junction leakage. Thus, it becomes impossible to form a shallow junction. The solid phase diffusion method has difficulty increasing the doping concentration of dopant in the solid phase diffusion source sufficient for a shallow junction having a low resistance. Also, there is a problem of precisely controlling the doping concentration of the dopant in the solid phase diffusion source.

### SUMMARY OF THE INVENTION

To solve the above-described problems, it is an object of the present invention to provide a method of fabricating an integrated circuit having a shallow junction in which dislocation does not occur and the doping concentration of impurities is precisely controlled.

Accordingly, to achieve the above object, according to an embodiment of the present invention, there is provided a method of fabricating an integrated circuit. A diffusion barrier layer pattern is formed on a semiconductor substrate. A SOG layer containing impurities is formed on the entire surface of the semiconductor substrate. The SOG layer may be formed by spin-coating and densifying a liquid silicate glass including one of P, B, In, As, and Sb doping elements. The SOG layer may be formed by chemical vapor deposition (CVD) using a compound gas including SiH₄, O₂, and one of P, B, In, As, and Sb doping elements.

Impurity ions are additionally implanted into the SOG layer by a plasma ion implantation method to increase the concentration of impurities in the SOG layer. The concentration of impurities of the SOG layer may be increased using a plasma ion implanter including a Plasma Immersion Ion Implanter (PIII) and an Ion Shower Implanter (ISI). The maximum impurity implantation concentration of the SOG layer additionally implanted with the impurity ions may be adjusted to 10¹⁹-10²³ cm⁻³. The impurity ions may be implanted into only portions of the SOG layer formed on the diffusion barrier layer and the semiconductor substrate when the impurity ions are additionally implanted into the SOG layer.

The impurity ions contained in the SOG layer having the selectively increased concentration of impurities are diffused into the semiconductor substrate by a solid phase diffusion method to form shallow junctions. The shallow junctions may be formed by the solid phase diffusion method using one of rapid thermal annealing (RTA), spike annealing, and laser annealing. The shallow junctions may have a doping depth of 50 nm or less on the semiconductor substrate and a doping concentration of 10¹⁸-10²² cm⁻³.

According to another embodiment of the present invention, there is provided a method of fabricating an integrated circuit. A gate pattern is formed on a semiconductor substrate. A SOG layer containing impurities is formed on the entire surface of the semiconductor substrate. It is preferable that the ratio of the thickness of the SOG layer to the height of a gate electrode constituting the gate pattern is between 1:1.5 and 1:10. The SOG layer may be formed by spin-coating and densifying a liquid silicate glass including one of P, B, In, As, and Sb doping elements. The SOG layer may be formed by CVD using a compound gas including SiH₄, O₂, and one of P, B, In, As, and Sb doping elements.

Impurity ions are additionally implanted into portions of the SOG layer formed on the gate pattern and the semiconductor substrate by a plasma ion implantation method to selectively increase the concentration of impurities of the SOG layer. The concentration of impurities of the SOG layer may be selectively increased using a plasma ion implanter including a PIII or an ISI. It is preferable that the maximum impurity implantation concentration of the SOG layer additionally implanted with the impurity ions is adjusted to 10¹⁹-10²³ cm⁻³.

The impurity ions contained in the SOG layer diffused into the semiconductor substrate by a solid phase diffusion method to form shallow junctions having a LDD/SDE region and a highly doped source/drain region self-aligned underneath both sidewalls of the gate pattern. The shallow junctions may be formed by the solid phase diffusion method using one of rapid thermal annealing (RTA), spike annealing, and laser annealing. The shallow junctions may have a doping depth of 50 nm or less on the semiconductor substrate and a doping concentration of 10¹⁸-10²² cm⁻³.

As a result, the concentration of impurities is precisely controlled by the plasma ion implantation method, and impurity ions are not directly implanted into the semiconductor substrate. Thus, the crystal structure of the semiconductor substrate is not damaged. Moreover, a LDD region and a highly doped source/drain region can be formed by a self-aligned method.

### BRIEF DESCRIPTION OF THE DRAWINGS

The above object and advantages of the present invention will become more apparent by describing in detail preferred embodiments thereof with reference to the attached drawings in which:

FIGS. 1 through 4 are cross-sections explaining a method of fabricating an integrated circuit having a shallow junction according to a first embodiment of the present invention; and

FIGS. 5 through 8 are cross-sections explaining a method of fabricating an integrated circuit having a shallow junction according to a second embodiment of the present invention.

### DETAILED DESCRIPTION OF THE INVENTION

Hereinafter, embodiments of the present invention will be described in detail with reference to the attached drawings. However, the embodiments of the present invention may be modified into various other forms, and the scope of the present invention must not be interpreted as being restricted to the embodiments. Rather, the embodiments are provided to more completely explain the present invention to those skilled in the art. In drawings, the thicknesses of layers or regions are exaggerated for clarity. Like reference numerals in the drawings denote the same members. Also, when it is written that a layer is formed “on” another layer or a substrate, the layer may be formed directly on the other layer or the substrate, or other layers may intervene therebetween.

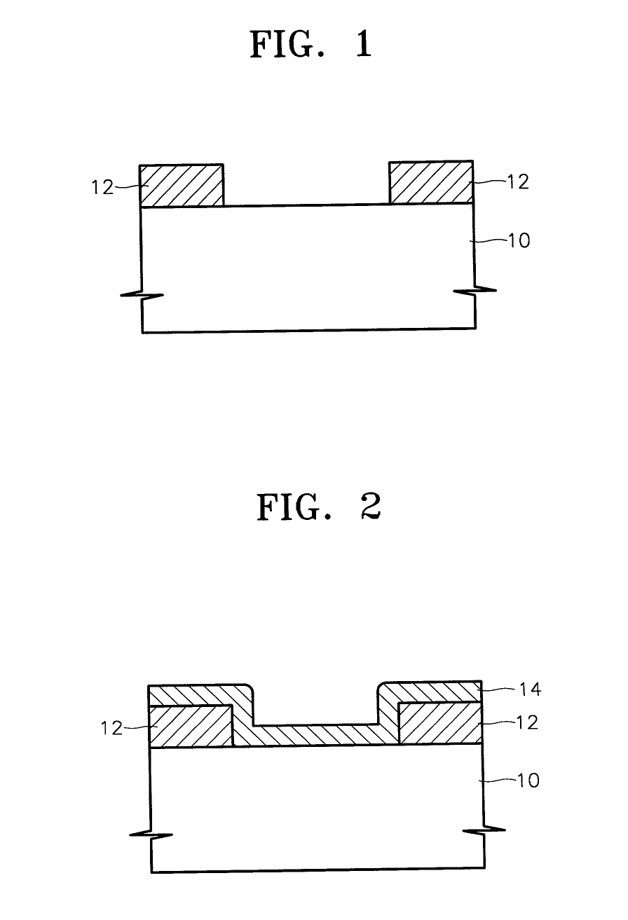

FIGS. 1 through 4 are cross-sections explaining a method of fabricating an integrated circuit having a shallow junction according to a first embodiment of the present invention. Referring to FIG. 1, a diffusion barrier layer pattern 12 is formed on a semiconductor substrate 10, e.g., a p-type or n-type silicon substrate. The diffusion barrier layer pattern 12 is formed such that a portion of the semiconductor substrate 10 is exposed. The diffusion barrier layer pattern 12 is formed of oxide or nitride and serves to prevent dopant from being diffused into the semiconductor substrate 10.

Referring to FIG. 2, a silicon oxide glass (SOG) layer 14 is formed on the entire surface of the semiconductor substrate 10. The SOG layer 14 is formed to a thickness of 20-300 nm. The SOG layer 14 serves as a diffusion source as well as a buffer layer for preventing the semiconductor substrate 10 from being damaged during the implantation of plasma ions.

To form the SOG layer 14, a liquid silicate glass containing a doping element such as B, P, In, As, Sb, and the like is spin-coated and is heat-treated at a temperature of 200-600° C. for 2-30 minutes to be densified. A silicate glass containing B may be a borosilicate glass (BSG), and a silicate glass containing P may be a phosphosilicate glass (PSG). The SOG layer 14 may be formed at a temperature equal to or less than 400° C., preferably about 350° C., by chemical vapor deposition (CVD) using a compound gas containing SiH₄, O₂, and the doping element.

The term “SOG” is generally known as “spin-on-glass”, but is named “silicon oxide glass” in the detailed description of the present invention since the SOG layer can be formed by CVD.

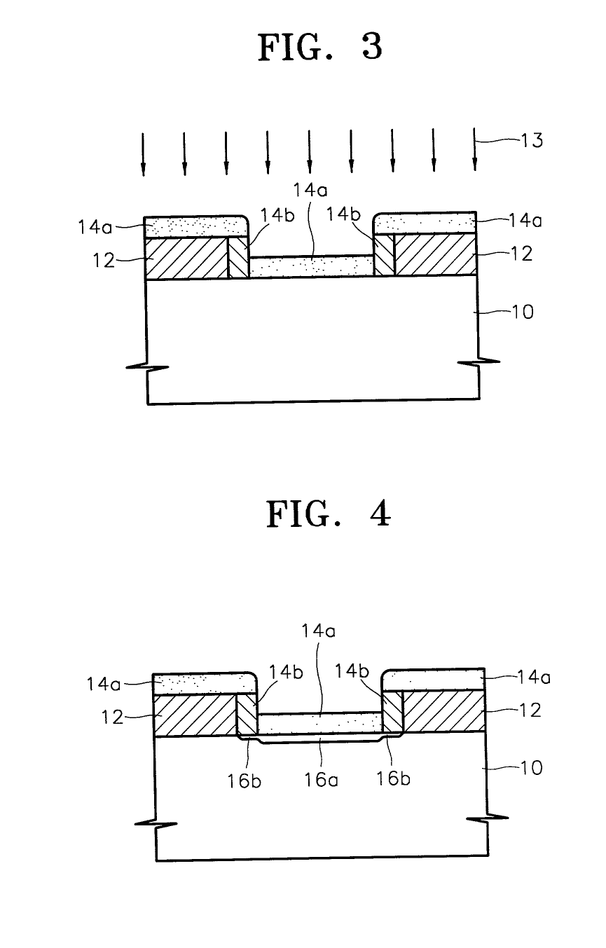

Referring to FIG. 3, impurity ions 13 are additionally implanted into the SOG layer 14 by a plasma ion implantation method to increase the impurity concentration of the SOG layer 14. In other words, the semiconductor substrate 10 on which the SOG layer 14 is formed is put into a plasma ion implanter to additionally implant the impurity ions 13 into the SOG layer 14. As a result, the doping concentration of a shallow junction that will be formed later can be precisely controlled, and damage to the crystal structure of the semiconductor substrate 10 does not occur.

The maximum impurity implantation concentration of the SOG layer 14, into which the impurity ions 13 is additionally implanted, is adjusted to 10¹⁹-10²³ cm⁻³. This is to maintain the doping depth of the shallow junction that will be formed later to a depth equal to or less than 50 nm with the doping concentration of the shallow junction within a range of 10¹⁸-10²² cm⁻³.

B or In impurities are implanted by the plasma ion implantation method if the semiconductor substrate 10 is an n-type silicon substrate. P, As, or Sb impurities are implanted by the plasma ion implantation method if the semiconductor substrate 10 is a p-type silicon substrate.

The plasma ion implanter may be a Plasma Immersion Ion Implanter (PIII) or an Ion Shower Implanter (ISI) using low acceleration voltages in which impurity ions are implanted in a predetermined direction. The PIII operates by generating plasma over a wafer, i.e., a semiconductor substrate, periodically applying negative voltages to the wafer, and accelerating plasma ions to bombard the wafer with the plasma ions. The ISI operates by extracting/accelerating plasma ions away from the wafer to a large area electrode to bombard the wafer with the plasma ions. In the plasma ion implanter, the impurity ions 13 radiated at low acceleration voltages may be implanted into the SOG layer 14 to a high dose of over 10¹⁵ cm⁻² without damaging to the crystal structure of the semiconductor substrate 10.

If the impurity ions 13 are implanted into the SOG layer 14 by the plasma ion implantation method using the plasma ion implanter, the impurity ions 13 having a high concentration of over 10²¹ cm⁻³ are selectively implanted into portions 14a of SOG layer 14 exposed to the vertically moving impurity ions 13, i.e., the portions 14a of the SOG layer 14 formed on the diffusion barrier layer pattern 12 and on the semiconductor substrate 10. The impurity ions 13 are not additionally implanted into portions 14b of the SOG layer 14 not exposed to the vertically moving impurity ions 13, i.e., a SOG layer 14b formed at the sidewalls of the diffusion barrier layer pattern 12, due to a shadow effect.

Finally, the portions 14a of the SOG layer 14 on the diffusion barrier layer pattern 12 and the semiconductor substrate 10 are a high concentration diffusion source, and the portions 14b of the SOG layer 14 at the sidewall of the diffusion barrier layer pattern 12 are a low concentration diffusion source. The characteristics of the impurity implantation of the SOG layer 14 depends on several factors including the kinetic energy and ion implantation dose of the impurity ions 13, the initial concentration of impurities of the SOG layer 14, the thickness of the SOG layer 14, and the thickness of the diffusion barrier layer pattern 12.

Referring to FIG. 4, the semiconductor substrate 10 on which the high concentration diffusion source and the low concentration diffusion source are formed is rapidly heat-treated to diffuse impurities from the SOG layer 14 into the semiconductor substrate 10. As a result, shallow junctions 16a and 16b are formed. In other words, the impurities in the SOG layer 14 are rapidly heat-treated and diffused by a solid phase diffusion method to form the shallow junctions 16a and 16b. Here, the shallow junction 16b is obviously shallower than the shallow junction 16a to be precise. Thus, the shallow junctions 16a and 16b are easily formed and the activation efficiency of the impurities in the SOG layer 14 is increased if the solid phase diffusion method is used.

The rapid heat-treatment represents a rapid thermal annealing (RTA), a spike annealing, or a laser annealing which is suitable for forming shallow junctions in solid phase diffusion. In the RTA, the semiconductor substrate 10 on which the high concentration diffusion source and the low concentration diffusion are formed is annealed at a temperature of 950-1150° C. for 1-1000 seconds in an inert gas atmosphere. Thus, shallow junctions 16a and 16b having a doping depth of 50 nm or less on the semiconductor substrate 10, preferably 8-35 nm, and a doping concentration of 10¹⁸-10²² cm⁻³ may be formed. In the spike annealing, the semiconductor substrate 10 on which the high concentration diffusion source and the low concentration diffusion source are formed is annealed at a temperature of 950-1200° C. in an inert gas atmosphere. Thus, shallow junctions 16a and 16b having a doping depth of 50 nm or less on the semiconductor substrate 10, preferably 8-35 nm, and a doping concentration of 10¹⁸-10²² cm⁻³ may be formed.

When the shallow junctions 16a and 16b are formed by the rapid heat-treatment, there is a difference between the doping concentration of the shallow junction 16a diffused from the high concentration diffusion source and the doping concentration of the shallow junction 16b diffused from the low concentration diffusion source. As a result, a high concentration shallow junction (16a) is formed near the surface of the semiconductor substrate 10, and a low concentration shallow junction (16b) is formed near the surface of the semiconductor substrate 10 close to the diffusion barrier layer pattern 12.

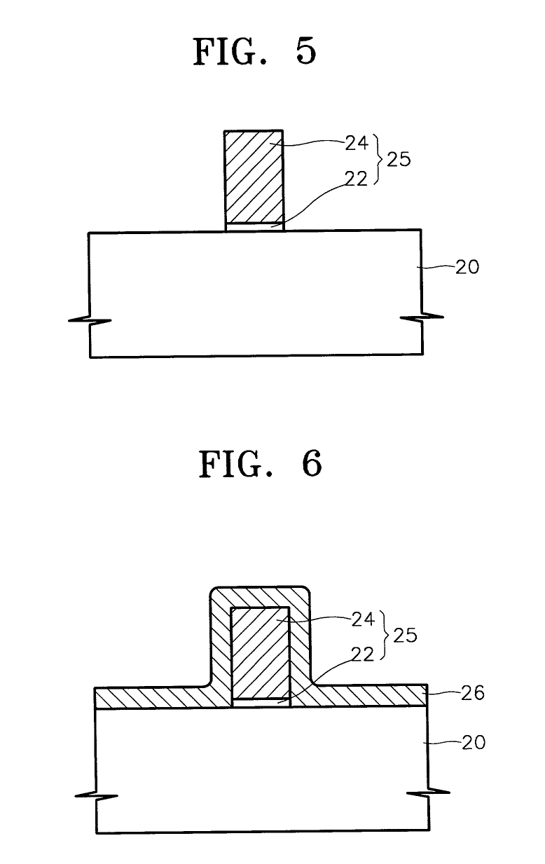

FIGS. 5 through 8 are cross-sections explaining a method of fabricating an integrated circuit having shallow junctions according to a second embodiment of the present invention. In detail, the inventive spirit of the first embodiment is applied to the method of fabricating an integrated circuit according to the second embodiment after a gate electrode is formed.

Referring to FIG. 5, a gate pattern 25 consisting of a gate oxide layer 22 and a gate electrode 24 is formed on a semiconductor substrate 20, i.e., an n-type or p-type silicon substrate. To form the gate pattern 25, the surface of the semiconductor substrate 20 is first oxidized to form a silicon oxide layer 22. Next, a polysilicon layer having a thickness of 100-300 nm is deposited on the silicon oxide layer 22 by low pressure chemical vapor deposition (LPCVD) and then patterned by a photolithographic process.

Referring to FIG. 6, a silicon oxide glass (SOG) layer 26 is formed on the entire surface of the semiconductor substrate 20. The SOG layer 26 is formed to a thickness of 20-30 nm and serves as a buffer layer for preventing damage to the semiconductor substrate 20 in a subsequent plasma ion implantation. The method of forming the SOG layer 26 is the same as the first embodiment.

The SOG layer 26 includes impurities containing a doping element having a conductivity type opposite to the conductivity type of the semiconductor substrate 20. For example, if the semiconductor substrate 20 is a p-type silicon substrate, the SOG layer 26 includes P, As, or Sb. If the semiconductor substrate 20 is an n-type silicon substrate, the SOG layer 26 includes B or In.

The ratio of the thickness of the SOG layer 26 to the height of the gate electrode 24 is 1:1.5 or more, preferably between 1:1.5 and 1:10 to take advantage of a shadow effect. Instead of P or B, As (or Sb) or In is selected as the doping element contained in the SOG layer 26 in consideration of a subsequent process for forming a lightly doped drain (LDD) region and source drain extension (SDE) region. Thus, the diffusion depth may be reduced in a subsequent heat treatment process.

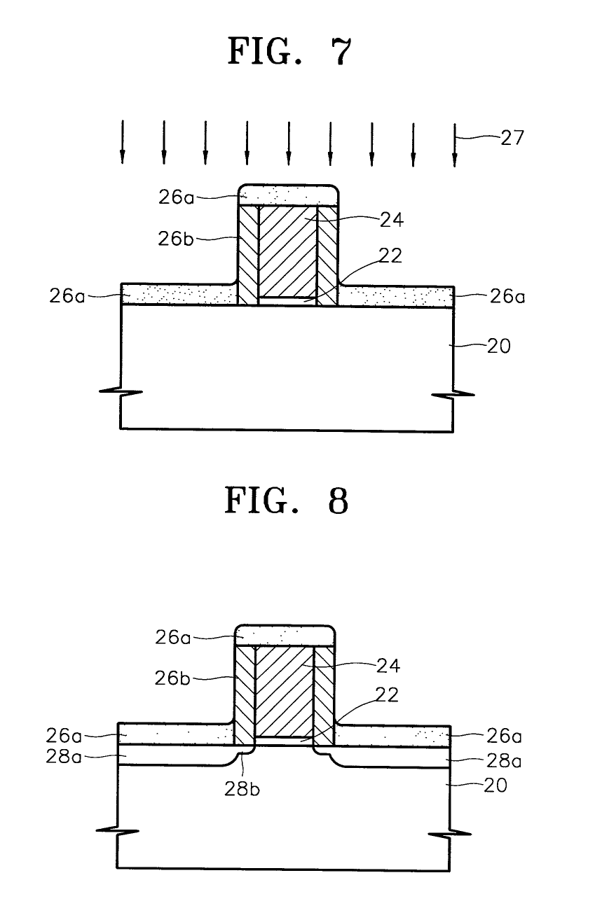

Referring to FIG. 7, impurity ions 27 are additionally implanted into the SOG layer 26 by a plasma ion implantation method to selectively increase the concentration of impurities of the SOG layer 26. In other words, the semiconductor substrate 20 on which the SOG layer 26 is formed is put into a plasma ion implanter and the impurity ions 27 are selectively additionally implanted into the SOG layer 26. As a result, the doping concentration of shallow junctions that will be formed later can be precisely controlled, and damage to the crystal structure of the semiconductor substrate 20 does not occur.

The maximum impurity implantation concentration of the SOG layer 26, into which the impurity ions 27 are additionally implanted, is adjusted to 10¹⁹-10²³ cm⁻³. This is to maintain the doping depth of the shallow junctions that will be formed later to a depth of 50 nm or less with the doping concentration of the shallow junctions within a range of 10¹⁸-10²³ cm⁻³.

B or In Impurities are implanted by the plasma ion implantation method if the semiconductor substrate 20 is an n-type silicon substrate. P, As, or Sb impurities are implanted by the plasma ion implantation method if the semiconductor substrate 20 is a p-type silicon substrate.

Due to the reason described above, if the SOG layer 26 is initially doped with heavier dopant atom such as As or Sb, lighter dopant atom such as P impurities are implanted into the SOG layer 26 by the plasma ion implantation method to easily produce S/D junction with a LDD/SDE region. In the similar way, if the SOG layer is initially doped with In, B impurities are implanted into the SOG layer 26 by the plasma ion implantation method.

The description of the plasma ion implanter was given with reference to FIG. 3, and thus will be omitted here to avoid repetition. In the plasma ion implanter, the impurity ions 27 radiated at low acceleration voltages may be implanted into the SOG layer 26 to a high dose of over 10¹⁵ cm⁻² without damaging to the crystal structure of the semiconductor substrate 20.

If the impurity ions 27 are implanted into the SOG layer 26 by the plasma ion implantation method using the plasma ion implanter, impurity ions 27 having a high concentration of over 10²¹ cm⁻³ are selectively implanted into portions 26a of the SOG layer 26 exposed to the vertically moving impurity ions 27, i.e., the planar portions 26a of the SOG layer 26 formed on the gate electrode 24 and on the semiconductor substrate 20. The impurity ions 27 are not additionally implanted into vertical portions 26b of the SOG layer 26 not exposed to the vertically moving impurity ions 27, i.e., the portions 26b of the SOG layer 26 formed at the sidewalls of the gate oxide layer 22 and the gate electrode 24 due to a shadow effect.

Finally, the portions 26a of the SOG layers 26 on the gate electrode 24 and the semiconductor substrate 20 are a high concentration diffusion source, and the portions 26b of the SOG layer 26 at the sidewalls of the gate oxide 22 and the gate electrode 24 are a low concentration diffusion source. The characteristics of the implantation of impurities of the SOG layer 26 depends on several factors including the kinetic energy and the implantation dose of impurity ions 27, the initial concentration of impurities of the SOG layer 26, and the thickness of the SOG layer 26.

Referring to FIG. 8, the semiconductor substrate 20 on which the high concentration diffusion source and the low concentration diffusion source are formed is rapidly heat-treated to diffuse the impurities in the SOG layer 26 into the semiconductor substrate 20. As a result, shallow junctions 28a and 28b are formed. In other words, the impurities in the SOG layer 26 is rapidly heat-treated and diffused by a solid phase diffusion method to form the shallow junctions 28a and 28b. Thus, the shallow junctions 28a and 28b are easily formed and the activation efficiency of the impurities in the SOG layer 26 is increased if the solid phase diffusion method is used. The description of the rapid heat treatment was given with reference to FIG. 4, and thus will be omitted here. The rapid heat treatment is performed under the same conditions as described with reference to FIG. 4.

When the shallow junctions 28a and 28b are formed by the rapid heat treatment, there is a difference between the doping concentration of the shallow junction 28a diffused from the high concentration diffusion source and the doping concentration of the shallow junction 28b diffused from the low concentration diffusion source. Thus, a source/drain region is formed as a high concentration shallow junction (28a) near the surface of the semiconductor substrate 20, and a LDD/SDE region is formed as a low concentration shallow junction (28b) near the surface of the semiconductor substrate 20 underneath the sidewalls of the gate oxide layer 22 and the gate electrode 24.

In other words, in this embodiment, the LDD/SDE region is self-aligned as the low concentration shallow junction (28b) near the surface of the semiconductor substrate 20 underneath both sidewalls of the gate pattern 25. The source/drain extension region is self-aligned as the high concentration shallow junction (28a) adjacent to the LDD region near the surface of the semiconductor substrate 20. The process of forming the LDD/SDE region and the highly doped source/drain region by a self-alignment method is simpler than a process of forming a LDD region and a highly doped source/drain region by two-time ion implantation using conventional sidewall spacers and is beneficially utilized as a process of forming nano-scale devices with shallow junctions.

As described above, in a method of fabricating an integrated circuit having shallow junctions according to the present invention, a SOG layer containing impurities is formed on a semiconductor substrate. Impurity ions are additionally implanted into the SOG layer containing the impurities by a plasma ion implantation method to increase the concentration of impurities selectively in the planar portions of the SOG layer. Next, the semiconductor substrate is rapidly heat-treated, and the impurities are diffused into the semiconductor substrate by a solid phase diffusion method to form shallow junctions. The concentration of impurities is precisely controlled by the plasma ion implantation method, and impurity ions are not directly implanted into the semiconductor substrate. Thus, the crystal structure of the semiconductor substrate is not damaged.

Moreover, if the method of fabricating the integration circuit having the shallow junctions according to the present invention is applied after a gate electrode is formed, a LDD region and a highly doped source/drain region can be formed by a self-aligned method.

What is claimed is:

1. A method of fabricating an integrated circuit comprising:
forming a diffusion barrier layer pattern on a semiconductor substrate;
forming a SOG layer containing impurities on the entire surface of the semiconductor substrate;
additionally implanting impurity ions into the SOG layer by a plasma ion implantation method to increase the concentration of impurities in the SOG layer; and
diffusing the impurity ions contained in the SOG layer having the increased concentration of impurities into the semiconductor substrate by a solid phase diffusion method to form shallow junctions.

2. The method of claim 1, wherein the SOG layer is formed by spin-coating and densifying a liquid silicate glass including one of P, B, In, As, and Sb doping elements.

3. The method of claim 1, wherein the SOG layer is formed by chemical vapor deposition (CVD) using a compound gas including SiH₄, O₂, and one of P, B, In, As, and Sb doping elements.

4. The method of claim 1, wherein the concentration of impurities of the SOG layer is increased using a plasma ion implanter including a Plasma Immersion Ion Implanter (Pill) and an Ion Shower Implanter (ISI).

5. The method of claim 1, wherein the maximum impurity implantation concentration of the SOG layer additionally implanted with the impurity ions is adjusted to 10¹⁹-10²³ cm⁻³.

6. The method of claim 1, wherein impurity ions are implanted into only portions of the SOG layer formed on the diffusion barrier layer and the semiconductor substrate when the impurity ions are additionally implanted into the SOG layer.

7. The method of claim 1, wherein the shallow junctions are formed by the solid phase diffusion method using one of rapid thermal annealing (RTA), spike annealing, and laser annealing.

8. The method of claim 7, wherein in the RTA, the semiconductor substrate on which the SOG layer having the increased concentration of impurities is formed is rapidly thermally annealed at a temperature of 950-1150° C. for 1-1000 seconds in an inert gas atmosphere.

9 The method of claim 7, wherein in the spike annealing, the semiconductor substrate on which the SOG layer having the increased concentration of impurities is formed is rapidly thermally annealed at a temperature of 950-1200° C. in an inert gas atmosphere.

10. The method of claim 1, wherein the shallow junctions have a doping depth of 50 nm or less on the semiconductor substrate and a doping concentration of 10¹⁸-10²² cm⁻³.

11. A method of fabricating an integrated circuit comprising:
forming a gate pattern on a semiconductor substrate;
forming a SOG layer containing impurities on the entire surface of the semiconductor substrate;
additionally implanting impurity ions into portions of the SOG layer formed on the gate pattern and the semiconductor substrate by a plasma ion implantation method to selectively increase the concentration of impurities of the SOG layer; and
diffusing the impurity ions contained in the SOG layer into the semiconductor substrate by a solid phase diffusion method to form shallow junctions having a LDD region and a highly doped source/drain region self-aligned underneath both sidewalls of the gate pattern.

12. The method of claim 11, wherein the ratio of the thickness of the SOG layer to the height of a gate electrode constituting the gate pattern is between 1:1.5 and 1:10.

13. The method of claim 11, wherein the SOG layer is formed by spin-coating and densifying a liquid silicate glass including one of P, B, In, As, and Sb doping elements.

14. The method of claim 11, wherein the SOG layer is formed by CVD using a compound gas including SiH₄, O₂, and one of P, B, In, As, and Sb doping elements.

15. The method of claim 11, wherein the concentration of impurities of the SOG layer is selectively increased using a plasma ion implanter including a PIII or an ISI.

16. The method of claim 11, wherein the maximum impurity implantation concentration of the SOG layer additionally implanted with the impurity ions is adjusted to 10¹⁹-10²³ cm³.

17. The method of claim 11, wherein the shallow junctions are formed by the solid phase diffusion method using one of rapid thermal annealing (RTA), spike annealing, and laser annealing.

18. The method of claim 17, wherein in the RTA, the semiconductor substrate on which the SOG layer having the increased concentration of impurities is formed is rapidly thermally annealed at a temperature of 950-1150° C. for 1-1000 seconds in an inert gas atmosphere.

19. The method of claim 17, wherein in the spike annealing, the semiconductor substrate on which the SOG layer having the increased concentration of impurities is formed is rapidly thermally annealed at a temperature of 950-1200° C. in an inert gas atmosphere.

20. The method of claim 11, wherein the shallow junctions have a doping depth of 50 nm or less on the semiconductor substrate and a doping concentration of 10¹⁸-10²² cm⁻³.
